(19) United States
(12) Patent Application Publication
(10) Pub. No.: US 2018/0298520 A1
(43) Pub. Date: Oct. 18, 2018

(54) Self-limited organic molecular beam epitaxy for precisely growing ultrathin C8-BTBT, PTCDA and their heterojunctions on surface

(71) Applicant: Nanjing University, Nanjing (CN)

(72) Inventors: Xinran WANG, Nanjing (CN); Bing Wu, Nanjing (CN); Yi SHI, Nanjing (CN); Daowei HE, Nanjing (CN)

(73) Assignee: Nanjing University, Nanjing (CN)

(21) Appl. No.: 15/488,532

(22) Filed: Apr. 17, 2017

(51) Int. Cl. C30B 23/06; C30B 23/02; C30B 29/54; C30B 29/68; H01L 51/00

(52) U.S. Cl. CPC C30B 23/066; C30B 23/025; C30B 29/54; C30B 29/68; H01L 51/0053; H01L 51/003; H01L 2251/556; H01L 51/0074; H01L 51/001

(57) ABSTRACT

Disclosed is a method for depositing ultrathin C₈-BTBT, PTCDA and their heterojunctions with precise control of the molecular layers. In the method, source of the organic semiconductor material to grow (C₈-BTBT or PTCDA) and a support are spaced from each other in a vacuum chamber with a temperature gradient, and ultrathin organic semiconductor crystal can be deposited on the support in crystalline form and with precisely controlled molecular layers. The as-deposited C₈-BTBT or PTCDA crystals can be one-molecular-layer or two-molecular-layer in thickness and has full coverage on the support without any additional layers or voids. Ultrathin heterojunctions of these two-dimensional organic semiconductors can also be achieved.

### TECHNICAL FIELD

The present invention aims to provide a method of producing ultrathin crystalline layers of C8-BTBT, PTCDA and ultrathin layered heterostructures of them with precise control of thickness. The as-produced form of materials is applicable to various organic devices including light emitting diodes, light emitting transistors, thin film transistors, photodetectors, and organic quantum well superlattices and device applications therein.

### BACKGROUND ART

Technique for producing ultrathin organic crystalline semiconductors and heterostructures with precise control is extremely important for material research and for realizing various organic devices including light emitting diodes, light emitting transistors, thin film transistors, photodetectors, and organic quantum well superlattices.

However, most techniques to produce organic thin films are difficult to precisely control the number of molecular layers. In commonly used thermal evaporation, the deposited films usually have variations in the local thickness^{[1]}. Although self-assembled mono-layer (SAM) technique can be used to produce monolayer organic thin-film on many surfaces^{[2]}, it is challenging to realize layer-by-layer heterostructures for advanced electronic and optoelectronic device applications. Organic molecular beam epitaxy (OMBE) can achieve precise control on material's thickness and quality with the help of ultrahigh vacuum and in situ monitoring system^{[3]}, but it is difficult to achieve large-scale uniform layered crystal and the equipment needed is very expensive.

The above problem is due to the fact that organic crystals are bound by much weaker van der Waals (vdW) forces, rather than covalent bond in inorganic crystals which leads to easier control on atomical layers as molecular beam epitaxy (MBE) does^{[4]}. The present invention is achieved by exploiting the vdW interactions and aiming to produce ultrathin organic crystalline semiconductors and heterostructures with much cheaper equipment.

### SUMMARY OF THE INVENTION

The present inventors have conducted extensive studies and developed a method for precisely growing ultrathin mono- to few-layer crystal of C8-BTBT and PTCDA on a support, like graphene. In this method, source of the organic semiconductor material to grow and a support are spaced from each other in a vacuum chamber and subjected to a temperature gradient, and ultrathin organic semiconductor crystal can be deposited on support with precisely controlled molecular layers in a self-limited manner. The as-deposited ultrathin C8-BTBT or PTCDA crystal can be one-molecular-layer to few-molecular-layer in thickness and has full coverage on the support without any additional layers or defects. The thickness depends on the local temperature of the support, not on the deposition time. This aspect is highly desirable to reduce the variations brought by deposition time.

One aspect of the present invention relates to a method for precisely growing two-dimensional layers of crystal of an organic semiconductor material on a crystalline surface of a support. The organic semiconductor material can be C₈-BTBT or PTCDA. The method comprises the steps of
1) placing a support and a source of the organic semiconductor material in a vacuum chamber, in which the source and the support are spaced from each other,
2) applying a temperature gradient between the source and the support, wherein the temperature of the source is set such that the organic semiconductor material begins to evaporate or sublime, and the source temperature is higher than that of the support,
3) allowing the molecules of the organic semiconductor material to evaporate or sublime at the source temperature and grow on the crystalline surface of the support, and
4) controlling the temperature of the support in an appropriate range and giving enough time so that one or two layers of the organic crystal can be deposited on the support.

In the tube furnace, an open container (about 1 cm in size) containing C₈-BTBT powder (from Sigma-Aldrich co. LLC) was placed in the quartz tube chamber. Then the graphene sample was placed 2-10 cm away from the source. The quartz tube chamber was sealed and evacuated by a turbo molecular pump to about 4×10⁶ Torr. The C₈-BTBT powder was then heated to 120° C. to start the growth. After 5 growth, the furnace was turned off and the sample was cooled down to room temperature with the vacuum condition maintained. 5 minutes′, 10 minutes′, 20 minutes' and repeated growth was carried out. As a result, a monolayer of C₈-BTBT was grown on graphene. These samples are shown in FIG. 3. When growing with the distance between the support and the source is 11-13 cm, a bilayer of C₈-BTBT was grown on graphene, as shown in FIG. 4.

In the same tube furnace, we replaced the source with PTCDA powder (from Sigma-Aldrich co. LLC) to perform the growth of PTCDA. The graphene sample was placed 2-5 cm away from the source. The quartz tube chamber was sealed and evacuated by a turbo molecular pump to about 4×10⁶ Torr. The PTCDA powder was then heated to 280° C. to start the growth. 5 minutes′, 30 minutes' and repeated growth was carried out. As a result, a monolayer of PTCDA was grown on graphene.

The self-limited growth of C₈-BTBT and PTCDA was also successfully repeated on hexagonal boron nitride (hBN) with other growth condition unchanged.

Another aspect of the present invention relates to a method for precisely growing heterojunction comprising two-dimensional layers of C₈-BTBT and PTCDA on a crystalline surface of a support, and the method comprises the steps of
1) growing a monolayer of crystal of PTCDA using the method described in the first aspect of the present invention, and
2) replacing the source with C₈-BTBT, using the as-deposited PTCDA crystal as the new support and repeating the C₈-BTBT bilayer's growth.

As a result, heterojunction of PTCDA monolayer and C₈-BTBT bilayer was grown on graphene. This sample is shown in FIG. 6.

The as-grown 2D organic crystal and organic heterojunction are applicable to various organic devices including light emitting diodes, light emitting transistors, thin film transistors, photodetectors, and organic quantum well superlattices.

### DESCRIPTION OF THE DRAWINGS

FIG. 1 shows (a) a schematic configuration of the equipment for implementing the method in accordance with an embodiment of the present invention and (b) a temperature gradient inside the vacuum chamber measured in an embodiment of the method;

FIG. 2 shows (a) a schematic diagram of the layered structure of C₈-BTBT crystal packed on graphene and (b) calculated binding energy of a molecule on different support, indicating a gradient of van der Waals interaction between different layers;

FIG. 3 shows atomic force microscopy (AFM) images of growing a monolayer of C₈-BTBT on graphene; (a), (b) and (c) are the AFM images of the graphene supports and as-deposited C₈-BTBT monolayer crystals on graphene supports undergone growth with different time; (d) is the AFM images of a graphene support and as-deposited C₈-BTBT monolayer crystals on it undergone repeated growths;

FIG. 4 shows AFM images of growing bilayer of C₈-BTBT on graphene; (a), (b) and (c) are the AFM images of the graphene supports and as-deposited C₈-BTBT bilayer crystals on graphene supports undergone growth with different time; (d) is the AFM images of a graphene support and as-deposited C₈-BTBT bilayer crystals on it undergone repeated growths;

FIG. 5 shows AFM images of growing monolayer of PTCDA on graphene; (a) and (b) are the AFM images of the graphene supports and as-deposited PTCDA monolayer crystals on graphene supports undergone growth with different time; (c) and (d) are Raman spectrum of the as-deposited PTCDA monolayer crystals in (a) and (b), respectively;

FIG. 6 shows (a), (b) and (c) optical micrographs and (d), (e) and (f) AFM images of growing heterojunction comprising PTCDA monolayer and C₈-BTBT bilayer on graphene support.

### DETAILED DESCRIPTION OF THE EMBODIMENTS

### Definitions

The term “C₈-BTBT” is short for 2,7-dioctyl[1]benzothieno[3,2-b][1]benzothiophene, a p-type small-molecule semiconductor (its formula is shown below).

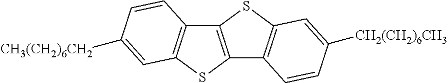

The term “PTCDA” is short for perylene-3,4,9,10-tetracarboxylic dianhydride, an n-type small-molecule semiconductor (its formula is shown below).

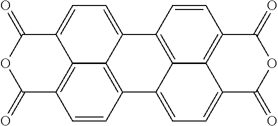 [SMILES: O=C1OC(=O)c2ccc3c4ccc5c6c(ccc(c7ccc1c2c73)c64)C(=O)OC5=O]

The term “self-limited” herein is used to describe such a kind of growth which terminates itself after a specific layer forms completely, though given enough source and time. That means a “self-limited growth” can produce complete layered crystal without adlayers, which has hardly been achieved before in vdW epitaxial small organic crystal. That is why the method we invented was named “self-limited organic molecular beam epitaxy”.

Unless otherwise indicated, the term “two-dimensional (2D) layer” or “monolayer” used herein means a one-atom-thick or one-molecule-thick crystalline layer of a substance, but its thickness may vary because of different packing configurations of the molecules constituting the crystalline layer. For example, a monolayer of C₈-BTBT is a one-molecule-thick layer of C₈-BTBT, the thickness of which may be approximately 0.6 to 3 nm depending on the packing configuration of C₈-BTBT molecules (see FIG. 2a).

The term “graphene” used herein refers to a monolayer of hexagonal carbon or a multiple layers of hexagonal carbon stacked upon one another. Graphene in the context of this specification may have a thickness of 0.3 to 10 nm, but not limited thereto.

The term “support” used herein refers to a physical base on which the organic semiconductor crystal can epitaxially grow. It supports epitaxy of organic crystal by providing a substantially smooth crystalline surface and van der Waals interaction, but is not necessarily rigid. For example, when the support is ultrathin graphene or hBN, it may be flexible.

The term “substrate” used herein refers to a physical base routinely used for an element or unit structure in electronic devices, which may comprise a metal, a metalloid, a semiconductor, an insulator, or a combination thereof. Substrate can also be flexible and optical transparent plastics. In the present invention, the support is positioned on the substrate in the specific examples disclosed. However, in other applications, the support may be the same as the substrate.

The term “vacuum” used herein refers to an environment at a pressure below one atmosphere (˜10⁵ Pa, or 760 Torr).

Method for Precisely Growth of 2D Layered Crystal

In one aspect, the present invention relates to a method for precisely growing two-dimensional layers of crystal of an organic semiconductor material on a crystalline surface of a support. The organic semiconductor material can be C₈-BTBT or PTCDA. The method comprises
1) placing a support and a source of the organic semiconductor material in a vacuum chamber, in which the source and the support are spaced from each other,
2) applying a temperature gradient between the source and the support by heating coils, wherein the temperature of the source is set such that the organic semiconductor material begins to evaporate or sublime, and the source temperature is higher than that of the support,
3) allowing the molecules of the organic semiconductor material to evaporate or sublime at the source temperature and grow on the crystalline surface of the support, and
4) controlling the temperature of the support in an appropriate range and giving enough time so that one or two layers of the organic crystal can be deposited on the support.

The method of the present invention can achieve ultrathin 2D C₈-BTBT and PTCDA crystal with full coverage on the support.

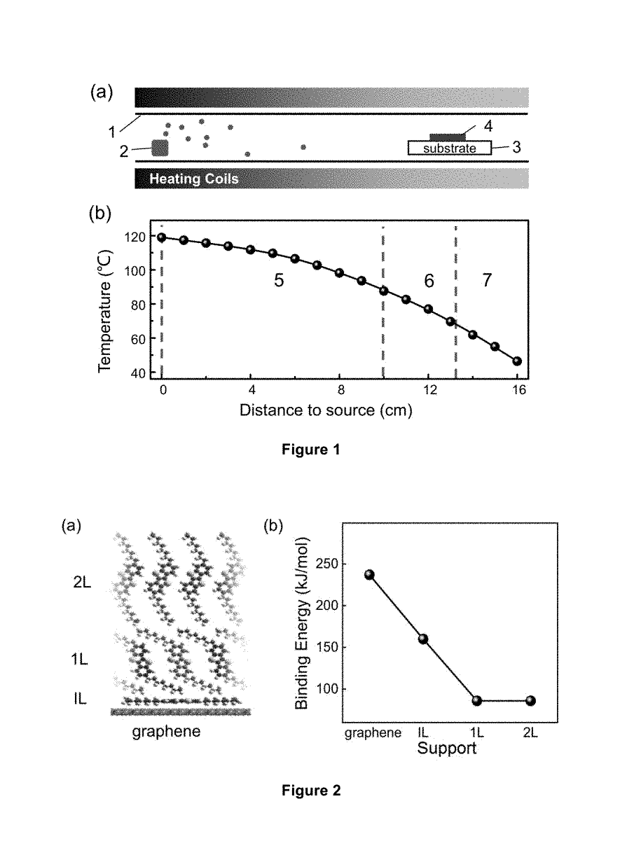

In an embodiment of the method, the vacuum chamber may be tube like and the support and the source of the organic semiconductor material are arranged horizontally in the tube-shaped chamber and are spaced from each other at a distance. FIG. 1a shows a schematic configuration of the equipment for implementing the method in accordance with an embodiment of the present invention. In FIG. 1a, 1 is a vacuum tube furnace; 2 is the source of an organic material; 3 is the substrate and 4 is the support. A turbo molecular pump (not shown) is connected to the tube 1 to evacuate the inside of the tube and maintain the pressure. The source 2 is placed in the center of the tube furnace. The distance between the source and the support is a key parameter to control the growth, because the temperature of the support depends highly on the distance as shown in FIG. 1b. In a preferred embodiment, the source is C₈-BTBT and the heating temperature is 120° C. FIG. 1b shows a temperature gradient inside the vacuum chamber measured when C₈-BTBT was growing. The temperature gradient created three zones with distinct growth behavior. When the support was placed in Zone 5 (2-10 cm), we can achieve a monolayer of 2D C₈-BTBT crystal; when the support was placed in Zone 6 (11-13 cm), we can achieve a bilayer of 2D C₈-BTBT crystal; while if the support was placed in Zone 7 (14-16 cm), we can achieve multilayered C₈-BTBT whose layer number was not well controlled.

To achieve self-limited organic molecular beam epitaxy, the organic semiconductor material to be deposited should have a gradient of van der Waals forces near the interface of the support, by exploiting which we can achieve the precisely controlled growth. In a preferred embodiment, the organic material is C₈-BTBT and the support is graphene. The C₈-BTBT-on-graphene structure has been extensively investigated and the molecular packing near the interface was found to be different from bulk crystal of C₈-BTBT^{[5]}. The thickness of the neighbouring two layers (namely the interfacial layer, IL, and the first layer, 1L) is ˜0.7 nm and ˜1.7 nm, respectively (see FIG. 2a). The thickness of the second layer (2L) and further layers is ˜3 nm, the same as that of bulk crystal^{[6]}. By performing molecular dynamics simulations, we calculated the C₈-BTBT-support binding energy to compare van der Waals forces on each layers. Here “C₈-BTBT-support binding energy” refers to the energy one single C₈-BTBT molecule needs to escape from a specific support. As shown in FIG. 2b, the binding energy is highest on graphene, but rapidly decreases on IL and 1L, indicating a gradient of van der Waals forces near the interface of graphene. Such binding energy gradient creates a temperature window where the adsorbed C₈-BTBT molecule is thermodynamically stable on graphene but not stable on IL. In another preferred embodiment, the organic material is PTCDA and the support is graphene.

In a preferred embodiment of the method, the pressure in the vacuum chamber may be any value below 10 Torr, preferably 10⁻³ Torr or less, more preferably 10⁻⁵ Torr or less.

The support in the method according to the present invention is not specifically limited, and any material can be used as the support as long as it can provide a substantially atomically smooth crystalline surface and a gradient of van der Waals interactions near the interface. In a preferred embodiment, the support is graphene. In this case, any kinds of graphene can be used, for example, mechanically exfoliated graphene, CVD graphene, or epitaxial graphene. The thickness of graphene can be from monolayer to about 10 nm, but not limited thereto. In another preferred embodiment, the support is hBN.

In an embodiment of the method, the deposition time of the organic semiconductor is not an important parameter, as long as it is long enough for the layered organic crystal to form completely. In a specific embodiment, the organic semiconductor material is C₈-BTBT and 5 minutes is enough for growth.

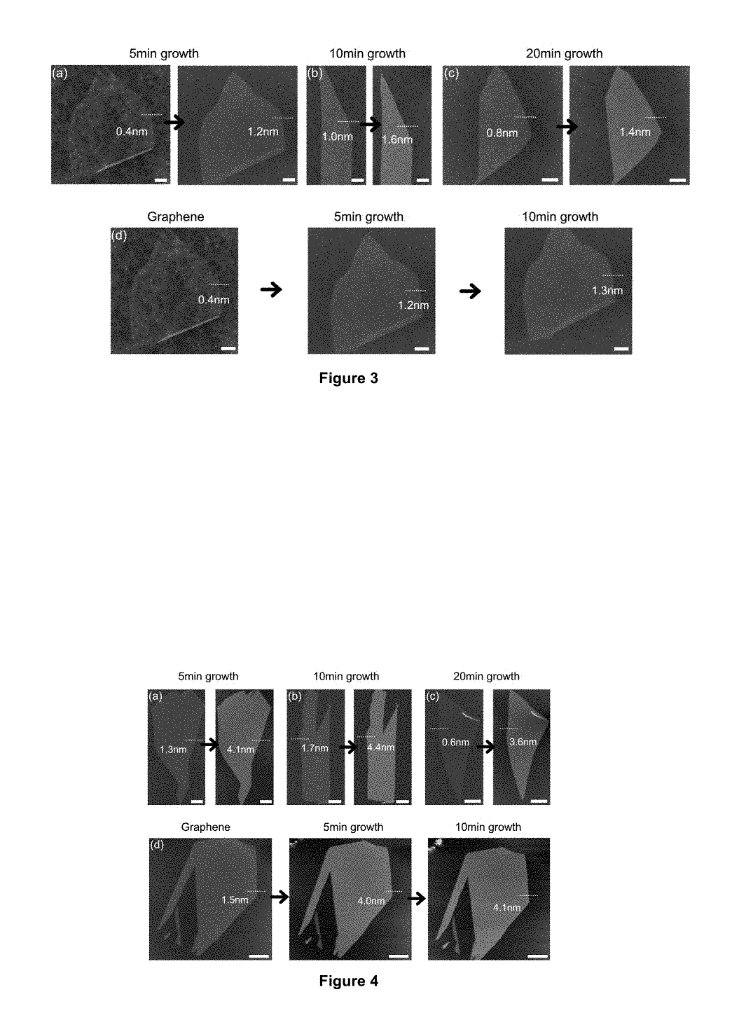

In a preferred embodiment, growth of C₈-BTBT monolayer crystal on graphene can be achieved. The growth of the 2D C₈-BTBT monolayer crystal by the method of the present invention can be confirmed by atomic force microscopy (AFM). FIG. 3 shows AFM images of growing monolayer of C₈-BTBT on graphene. FIG. 3a shows a piece of graphene undergone growth of 5 minutes. Because of its fragile nature, ultrathin organic small molecular crystal is not stable under emission of electron beam in TEM and SEM. So AFM test along with its thickness analysis is the most suitable tool to characterize the as-grown 2D organic crystal. The heights of the marked steps are labeled on the AFM images. After growth, the height was uniformly increased by ˜0.8 nm, consistent with the height of a monolayer of C₈-BTBT, 0.7 nm^{[5]} and the C₈-BTBT film shows atomic flatness without any visible defects or adlayers. The scale bars are 1 μm. FIGS. 3b and 3c show AFM images of graphene undergone 10 minutes' growth and 20 minutes' growth, respectively. The thickness change confirms the growth of monolayer of C₈-BTBT, as in FIG. 3a. Scale bars are 1 μm for (b) and 2 μm for (c). From FIGS. 3a, 3b and 3c, it can be seen that the morphology of the film did not further evolve after the monolayer was completed. FIG. 3d shows the same graphene in FIG. 3a undergone repeated growth. It can be seen that the further repeated growth did not result in additional layers.

In another preferred embodiment, growth of C₈-BTBT bilayer crystal on graphene can be achieved. Like FIG. 3, FIG. 4 shows AFM images of growing bilayer of C₈-BTBT on graphene undergone growth with different time or repeated growth. After growth, the height was uniformly increased by ˜2.7 nm, consistent with the height of bilayer of C₈-BTBT, 2.4 nm (0.7 nm+1.7 nm)^{[5]}. Scale bars are 3 μm for (a), 2 μm for (b) and (c) and 4 μm for (d). These experiments prove that the method for growing two-dimensional layers of crystalline organic semiconductor is highly precise, controllable and robust to experimental variations.

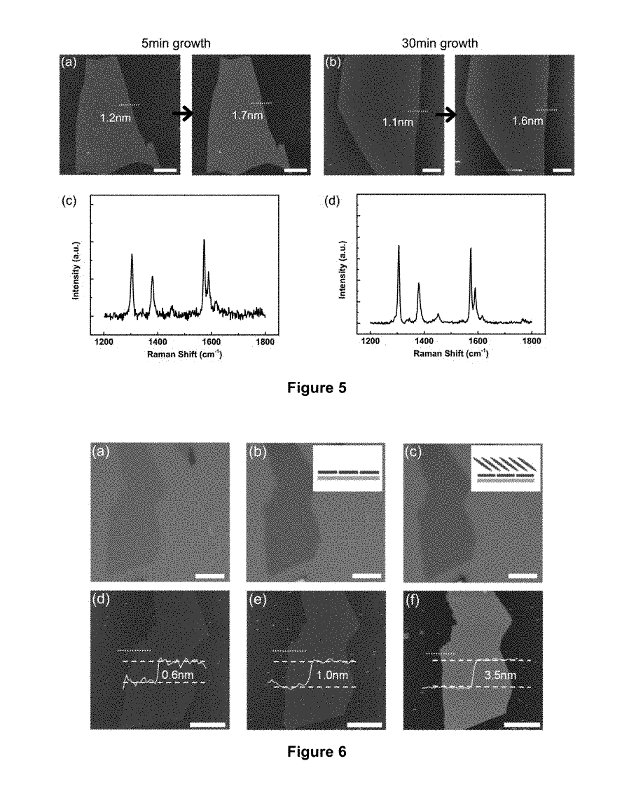

In a preferred embodiment, growth of PTCDA monolayer crystal on graphene can be achieved. PTCDA is a planar molecule favoring the face-on packing on graphene^{[7,8]}. Although the structure, properties and evaporation temperature of PTCDA are very different from C₈-BTBT, we are able to achieve growth of monolayer PTCDA on graphene. FIGS. 5a and 5b show AFM images of growing monolayer of PTCDA on graphene with different time. After growth, the height was uniformly increased by ˜0.4 nm, consistent with the height of monolayer of PTCDA, 0.37 nm. Since the thickness change was small, we measured Raman spectrum to confirm the growth. (c) and (d) are Raman spectrum of the as-deposited monolayer PTCDA crystals in (a) and (b), respectively. The clear Raman fingerprints of PTCDA confirmed the growth of PTCDA^{[9]}. Scale bars are 1.5 μm.

Method for Precisely Growth of 2D Heterojunction

Another aspect of the present invention relates to a method for precisely growing heterojunction comprising two-dimensional layers of C₈-BTBT and PTCDA on a crystalline surface of a support, and the method comprises the steps of
1) growing two-dimensional layers of crystal of PTCDA using the method described in the first aspect of the present invention, and
2) replacing the source with C₈-BTBT, using the as-deposited PTCDA crystal as the new support and repeating the growth.

In a preferred embodiment, self-limited growth of the heterojunction of PTCDA monolayer and C₈-BTBT bilayer on graphene can be achieved. FIG. 6 shows optical micrographs and AFM images of the growth. (a-c) show optical microscopic images of a graphene sample before growth (a), after growth of monolayer of PTCDA (b), and after growth of bilayer of C₈-BTBT on PTCDA (c), respectively. The color contrast of optical microscope images indicates the growth. The insets of (b, c) show the schematic illustrations of the structure. (d-f) show AFM images of the same sample before growth (a), after growth of monolayer of PTCDA (b), and after growth of bilayer of C₈-BTBT on PTCDA (c), respectively. The heights of the marked steps are labeled on the AFM images and the thickness changes are consistent with the height of monolayer of PTCDA and bilayer of C₈-BTBT. Scale bars are 5 μm.

The area for the substrate or support uses in the present invention can be any size or any shape, between 50-500 um².

In one embodiment, the area is between 50-100 um². In another embodiment, the area is between 100-200 um². In another embodiment, the area is between 200-300 um². In another embodiment, the area is between 300-400 um². In another embodiment, the area is between 400-500 um².

### EXAMPLES

### Example 1 Growth of a Monolayer of C₈-BTBT on Graphene

Graphene was exfoliated on a 285-nm SiO₂/Si substrate without further thermal treatment, to prepare a graphene sample having a surface area of about 50 μm². The exfoliated graphene was characterized by optical microscope, AFM and Raman spectroscopy before growth to obtain its thickness and topology information. The growth was carried out in a tube furnace as shown in FIG. 1. In the tube furnace, an open container (about 1 cm in size) containing C₈-BTBT powder (from Sigma-Aldrich co. LLC) was placed in the center of the quartz tube chamber (1 meter long and 2.5 cm in diameter). Then the graphene sample was placed 9 cm away from the source. The quartz tube chamber was sealed and evacuated by a turbo molecular pump to about 4×10⁶ Torr. The C₈-BTBT powder was then heated to 120° C. to start the growth. After 5 minutes' growth, the furnace was turned off and the sample was cooled down to room temperature with the vacuum condition maintained. As a result, a monolayer of C₈-BTBT was grown on graphene, as confirmed by AFM. Then a repeated 5 minutes' growth was carried out on this sample, and the further repeated growth did not result in additional layers. This example is shown in FIGS. 3a and 3d.

### Example 2

C₈-BTBT crystal was grown by the same method as in Example 1 except that the deposition time was changed to 10 minutes. As a result, a monolayer of C₈-BTBT was grown on graphene. This sample is shown in FIG. 3b.

### Example 3

C₈-BTBT crystal was grown by the same method as in Example 1 except that the deposition time was changed to 20 minutes. As a result, a monolayer of C₈-BTBT was grown on graphene. This sample is shown in FIG. 3c.

### Example 4 Growth of a Bilayer of C₈-BTBT on Graphene

C₈-BTBT crystal was grown by the same method as in Example 1 except that the distance between the support and the source was changed to 12 cm. As a result, a bilayer of C₈-BTBT was grown on graphene. This sample is shown in FIG. 4a.

### Example 5

C₈-BTBT crystal was grown by the same method as in Example 4 except that the deposition time was changed to 10 minutes. As a result, a bilayer of C₈-BTBT was grown on graphene. This sample is shown in FIG. 4b.

### Example 6

C₈-BTBT crystal was grown by the same method as in Example 4 except that the deposition time was changed to 20 minutes. As a result, a bilayer of C₈-BTBT was grown on graphene. This sample is shown in FIG. 4c.

### Example 7

C₈-BTBT crystal was grown by the same method as in Example 4. As a result, a bilayer of C₈-BTBT was grown on graphene. Then a repeated 5 minutes' growth was carried out on this sample, and the further repeated growth did not result in additional layers. This example is shown in FIG. 4d.

### Example 8 Growth of a Monolayer of C₈-BTBT on hBN

C₈-BTBT crystal was grown by the same method as in Example 1 except that the support was changed to hBN. As a result, a monolayer of C₈-BTBT was grown on hBN.

### Example 9

C₈-BTBT crystal was grown by the same method as in Example 8 except that the deposition time was changed to 20 minutes. As a result, a monolayer of C₈-BTBT was grown on hBN.

### Example 10 Growth of a Bilayer of C₈-BTBT on hBN

C₈-BTBT crystal was grown by the same method as in Example 4 except that the support was changed to hBN. As a result, a bilayer of C₈-BTBT was grown on hBN.

### Example 11

C₈-BTBT crystal was grown by the same method as in Example 10 except that the deposition time was changed to 20 minutes. As a result, a bilayer of C₈-BTBT was grown on hBN.

### Example 12 Growth of a Monolayer of PTCDA on Graphene

PTCDA crystal was grown by the same method as in Example 1 except that the source was replaced by PTCDA powder (from Sigma-Aldrich co. LLC), the heating temperature was changed to 280° C. and the distance between the support and the source was changed to 2 cm. As a result, a monolayer of PTCDA was grown on graphene. This sample is shown in FIG. 5a.

### Example 13

PTCDA crystal was grown by the same method as in Example 12 except that the deposition time was changed to 30 minutes. As a result, a monolayer of PTCDA was grown on graphene. This sample is shown in FIG. 5b.

### Example 14 Growth of a Monolayer of PTCDA on hBN

PTCDA crystal was grown by the same method as in Example 12 except that the support was changed hBN. As a result, a monolayer of PTCDA was grown on hBN.

### Example 15

PTCDA crystal was grown by the same method as in Example 14 except that the deposition time was changed to 30 minutes. As a result, a monolayer of PTCDA was grown on hBN.

### Example 16 Growth of Heterojunction of PTCDA and C₈-BTBT

PTCDA crystal was grown by the same method as in Example 12. Then C₈-BTBT crystal was grown by the same method as in Example 4 except that the substrate was replaced by the as-deposited PTCDA crystal on graphene. As a result, heterojunction of PTCDA monolayer and C₈-BTBT bilayer was grown on graphene. This sample is shown in FIG. 6.

The foregoing description of the embodiments has been provided for purposes of illustration and description. It is not intended to be exhaustive or to limit the disclosure. For a person skilled in the art, the embodiments and examples disclosed herein may be varied or modified in many ways without departing from the scope of the disclosure and such variations and modifications are included in the scope defined by the appended claims.

### REFERENCES

1. Ricardo Ruiz, et al. Adv. Mater. 17, 1795-1798 (2005).
2. J. Christopher Love, et al. Chem. Rev. 105, 1103-1170 (2005).
3. S. R. Forrest, Chem. Rev. 97, 1793-1896 (1997).
4. A. Y. Cho, et al. Prog. Solid State Chem. 10, 157-191 (1975).
5. Daowei He, et al. Nature Commun. 5, 5162-5162 (2014).
6. Hiromi Minemawari, et al. Nature 475, 36-367 (2011).
7. C. Kendrick, et al. Appl. Surf. Sci. 104-105, 586-594 (1996).
8. Han Huang, et al. ACS Nano. 3, 3431-3436 (2009).
9. V. Wagner, et al. Appl. Surf. Sci. 212-213, 520-524 (2003).

1. A method to achieve self-limited epitaxy of ultrathin organic semiconductors and heterojunctions, comprising
growing organic semi-conductors on a support in a self-limited manner by controlling the temperature of the support, wherein
the support is selected from graphene and hexagonal boron nitride; and the organic semi-conductors are selected from C8-BTBT and PTCDA;
comprising
preparing the support having a surface area of between 50-500 μm²;
exfoliating the support on a 285-nm SiO₂/Si substrate without further thermal treatment;
providing a quartz tube chamber for evaporation;
placing the organic semi-conductor on a center of the quartz tube chamber;
placing the support a first distance away from the center of the quartz tube chamber;
evacuating the quartz tube chamber after being sealed, by a turbo molecular pump to about 4×10⁶ Torr for 20 min;
heating the center the quartz tube chamber to a first temperature;
depositing a monolayer or bilayer of the organic semi-conductor on the surface of the support for a first period to form a self-limited epitaxy of ultrathin organic semiconductor;
wherein the method is characterized in that layer thickness of the organic material does not change when deposition time is longer than the first period.

2. The method of claim 1, wherein the support is graphene.

3. The method of claim 1, wherein the support is hexagonal boron nitride.

4. The method of claim 1, wherein the organic semi-conductor is C8-BTBT.

5. The method of claim 1, wherein the organic semi-conductor is PTCDA.

6. The method of claim 1, wherein the first distance is 2-13 cm.

7. The method of claim 6, wherein the first distance is 2-10 cm.

8. The method of claim 6, wherein the first distance is 11-13 cm.

9. The method of claim 6, wherein the self-limited epitaxy of ultrathin organic semiconductor is a monolayer.

10. The method of claim 8, wherein the self-limited epitaxy of ultrathin organic semiconductor is a bilayer.

11. The method of claim 4, wherein the first temperature is 120° C.

12. The method of claim 5, wherein the first temperature is 280° C.

13. The method of claim 6, wherein the first distance is 2-5 cm.

14. The method of claim 1, wherein the first period is between 5-30 minutes.

15. A method for growing two-dimensional layers of crystal of an organic semiconductor material on a crystalline surface of a support, wherein
the support is selected from graphene and hexagonal boron nitride,
the method comprising
growing a heterojunction of a monolayered first semiconductor material and bilayered second semiconductor material on the substrate, comprising
1) placing a first semi-conductor material at a source in a vacuum chamber;
2) placing the support and the source having the first organic semiconductor material apart from each other at a third distance;
3) applying a third temperature gradient between the first organic semiconductor material and the support, wherein the temperature of the source is set such that the first organic semiconductor material can evaporate or sublime, and the source temperature is higher than that of the support;
4) forming a monolayer of the first semiconductor material on the support after a third period;
5) placing the monolayer of the first semiconductor material on the support from step 4 at the source in the vacuum chamber;
6) placing a second semi-conductor material at the source in the vacuum chamber;
7) placing the support bearing the monolayer of the first semiconductor material and the source having the second organic semiconductor material apart from each other at a fourth distance;
8) applying a fourth temperature gradient between the second organic semiconductor material and the support, wherein the temperature of the source is set such that the second organic semiconductor material can evaporate or sublime, and the source temperature is higher than that of the support bearing the monolayer of the first semiconductor material;
9) forming a bilayer of the second semiconductor material on the support having a monolayer of the first semi-conductor material after a fourth period wherein steps 1-9 are sequential method steps.

16. The method of claim 15, wherein the first semiconductor material is PTCDA.

17. The method of claim 15, wherein the second semiconductor material is C₈-BTBT.

18. The method of claim 16, wherein the third distance is less than 5 cm.

19. The method of claim 17, wherein the fourth distance is between 11-13 cm.

20. The method of claim 15, wherein the ultrathin organic semiconductor is part of an organic semi-conducting device.
